(19) United States
(12) Patent Application Publication
(10) Pub. No.: US 2005/0109390 A1
(43) Pub. Date: May 26, 2005

(54) Photoelectric conversion device and solar cell comprising same

(75) Inventors: Masatsugu Shimomura, Wako-shi (JP); Sachiko I. Matsushita, Wako-shi (JP); Nobuko Fukuda, Wako-shi (JP); Takashi Isoshima, Wako-shi (JP); Masahiko Hara, Wako-shi (JP)

Correspondence Address: BIRCH STEWART KOLASCH & BIRCH, PO BOX 747, FALLS CHURCH, VA, 22040-0747, US

(73) Assignee: RIKEN, Wako-shi (JP)

(21) Appl. No.: 10/927,015

(22) Filed: Aug. 27, 2004

(30) Foreign Application Priority Data
Aug. 28, 2003 (JP) 303979/2003

(51) Int. Cl. H01L 31/00

(52) U.S. Cl. 136/263; 136/252

(57) ABSTRACT

Disclosed is a high-efficiency photoelectric conversion device which comprises a photonic crystal consisting essentially of a photoelectric conversion substance, and a light-emitting dye contained inside the photonic crystal, and in which the photonic crystal has a periodic structure that retards the light emission by the light-emitting dye.

### FIELD OF THE INVENTION

The present invention relates to a photoelectric conversion device comprising dye, and to a solar cell comprising the device.

### DESCRIPTION OF THE BACKGROUND

Heretofore, photoelectric conversion devices are specifically noted in the art. The photoelectric conversion device is, for example, a device which receives sunlight to excite the dye therein and the excited electrons are transferred to a semiconductor to generate a current running therein. The device of the type is ecological and inexpensive and is easy to produce, and therefore, it is expected to be a hopeful device of utilizing sunlight energy. FIG. 8A is an outline view showing a solar cell (a type of photoelectric conversion device) that comprises a conventional photoelectric conversion device. In this, the dye is excited by the light energy applied thereto, and the resulting electrons are transferred to the conductor via titanium oxide therein. In general, however, it is said that the photoelectric conversion efficiency of the device is 33% as a theoretical value, but its actual value is about 8% and is low.

JP-A-2003-197281 discloses a fact that, when at least one specific merocyanine dye is used as a photoelectric conversion material in such a device, then it increases the photoelectric conversion efficiency of the device.

JP-A-2003-215366 discloses a fact that a photoelectric conversion device having a thin layer of oxide semiconductor particles with a specific methine dye held thereon may have an increased photoelectric conversion efficiency.

JP-A-2003-217688 and 2003-218372 disclose a discussion of improving the photoelectric conversion efficiency of a solar cell from the structural viewpoint thereof.

However, the above-mentioned methods could not bring about a fundamental solution of the problems with the photoelectric conversion efficiency of the devices. In conventional photoelectric conversion devices of the type, as in FIG. 8B, some percentage of the electrons excited by light may move to any other level inside the dye, not moving to the semiconductor, and may be used for light emission. So far as this point could not be solved, a significant improvement of the photoelectric conversion efficiency of the devices could not be expected.

Given that situation, we, the present inventors have hit an idea of applying a technique of photonic crystals to photoelectric conversion devices. The photonic crystal is a two-dimensional or three-dimensional artificial crystal structure formed of a dielectric substance having a period of about the wavelength of light. For example, in a photonic crystal that shuts up light of hν2 as in FIG. 8B, light emission of the dye having an emitting light wavelength of hν2 is retarded. This suggests the possibility of the change of the life of excited electrons. In this connection, the present inventors have considered that, if the electron life is influenced by photonic crystals, then the electron transfer process to the conduction band of any other atom, or that is, the photoelectric reaction may also be influenced by them.

Accordingly, the present inventors have decided to utilize the light band region of photonic crystals to thereby provide a high-efficiency photoelectric conversion device.

### SUMMARY OF THE INVENTION

We, the present inventors have investigated the above-mentioned problems, and, as a result, have fount that, when a photonic crystal is formed of a photoelectric conversion substance and when a light-emitting dye is incorporated inside it, then a high-efficiency photoelectric conversion device can be obtained. Based on the findings, the present inventors have provided the following inventions:

(1) A photoelectric conversion device, which comprises a photonic crystal consisting essentially of a photoelectric conversion substance, and a light-emitting dye contained inside the photonic crystal, and in which the photonic crystal has a periodic structure that retards the light emission by the light-emitting dye.

(2) The photoelectric conversion device of (1), wherein the light-emitting dye has an absorption in the UV, visible and/or IR range and can emit light in the UV, visible and/or IR range.

(3) The photoelectric conversion device of (1), wherein the light-emitting dye is any one or more of ruthenium dyes, coumarin dyes and porphyrin dyes.

(4) The photoelectric conversion device of (1), wherein the light-emitting dye is a ruthenium dye.

(5) The photoelectric conversion device of any one of (1) to (4), wherein the photoelectric conversion substance is any one or more of titanium oxide, zinc oxide, strontium titanate, tin oxide, tungsten trioxide, dibismuth trioxide, ferric oxide and zirconia.

(6) The photoelectric conversion device of any one of (1) to (4), wherein the photoelectric conversion substance is titanium oxide.

(7) The photoelectric conversion device of (1), wherein the light-emitting dye is a ruthenium dye and the photoelectric conversion substance is titanium oxide.

(8) The photoelectric conversion device of (1), wherein the photonic crystal contains the following structure:

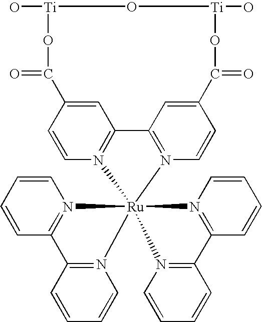

(9) The photoelectric conversion device of any one of (1) to (8), wherein the thickness of the photonic crystal layer is from 500 nm to 1 mm.

(10) The photoelectric conversion device of any one of (1) to (9), wherein the photonic crystal contains the light-emitting dye in an amount of from 5.0⁻⁹ to 2.0⁻⁵ mol per 1 cm² of the surface of the photonic crystal.

(11) The photoelectric conversion device of any one of (1) to (10), wherein the photonic crystal has any of a cubic closest packing structure, a hexagonal closet packing structure, or a face-centered cubic structure.

(12) A photoelectric conversion device, which comprises an electrolyte, a first electrode and a second electrode kept in contact with the electrolyte, a photonic crystal layer consisting essentially of a photoelectric conversion substance and provided on one face or both faces of the first electrode, and a light-emitting dye contained inside the photonic crystal layer, and in which the photonic crystal has a periodic structure that retards the light emission by the light-emitting dye.

(13) The photoelectric conversion device of (12), wherein the electrolyte is one or more of amine-type, iodide ion-type and cobalt complexes.

(14) The photoelectric conversion device of (12) to (13), wherein the first electrode is an ITO glass electrode.

(15) The photoelectric conversion device of any one of (12) to (14), wherein the second electrode is formed of any of platinum, silver, copper, nickel or gold.

(16) The photoelectric conversion device of (12) or (13), wherein the first electrode is an ITO glass electrode and the second electrode is formed of platinum.

(17) A solar cell comprising the photoelectric conversion device of any one of (12) to (16).

### BRIEF DESCRIPTION OF THE DRAWINGS

FIG. 1 is an outline view showing an example of producing a photonic crystal;

FIG. 2 is a graph showing a relationship between the time for electrophoresis and the pH of titanium oxide gel;

FIG. 3 shows electromicroscopic pictures of a photonic crystal;

FIG. 4 shows an outline of a method for measuring the photoelectric conversion efficiency of a photonic crystal;

FIG. 5 shows the photoelectric conversion efficiency of incident monochromatic light;

FIG. 6 shows the photoelectric conversion efficiency of monochromatic light per mol of dye;

FIG. 7 shows a relationship between the life of excited electrons and the presence or absence of a photonic crystal structure; and

FIG. 8 is an outline view showing a conventional solar cell.

### BEST MODE FOR CARRYING OUT THE INVENTION

The photonic crystal as referred to herein means a periodic structure of around the wavelength of light. In the invention, the periodic structure which is formed through near-field resonance of such a photonic crystal and which does not transmit a specific light through it is utilized in a photoelectric conversion device. Specifically, a light-emitting dye is incorporated inside a photonic crystal that does not transmit the light emitted by the dye therein, and the photonic crystal with the dye therein thus retards the light emission by the dye and, as a result, the light energy conversion efficiency of the device with the photonic crystal therein is thereby increased. The terminology, retardation as referred to herein is meant to include both partial retardation of light emission by the light-emitting dye and complete retardation thereof.

The method of fabricating the periodic structure of a photonic crystal is not specifically defined, and any known technique may broadly apply to it. One example is the method described in JP-A-11-71138. Concretely, it comprises (1) applying particles onto a substrate to form a particulate layer thereon, (2) then applying a photoelectric conversion substance and/or a photoelectric conversion substance precursor to the gap of the particulate layer or on the particles, (3) optionally converting the photoelectric conversion substance precursor into the photoelectric conversion substance thereof, and (4) removing a part and/or all of the particulate layer to fabricate the intended periodic structure. After that, if desired, the photonic crystal film may be peeled off from the substrate.

The method as above gives a thin-layered photonic crystal of a periodic structure that follows the self-organizing control structure of specific particles. Preferably, the self-organizing control structure to form the photonic crystal layer is a 1- to 100-layered structure. This may control a period of from 10 nm to 40 μm. In this, the photonic crystal must be so planned that its period is calculated so as to shut up the light emitted by the light-emitting dye therein. The period that shuts up the light emitted by the light-emitting dye may be determined by calculation formulae, depending on the wavelength of the light to be emitted by the light-emitting dye, the photoelectric conversion substance, and, when the photoelectric conversion device is used as a solar cell, then further on the electrolyte and the dielectric constant of the electrode substrate, etc. For example, the calculation method described in Physical Review B 66, 045101, 2002 may be employed. It is not always necessary that the periodic structure corresponds to the data obtained through calculation and may be suitably modified within the range to attain the object of the invention. The modification range may be within ±10 nm, preferably within ±5 nm.

The thickness of the photonic crystal layer in the invention is not specifically defined. When the photoelectric conversion device is employed as a solar cell, then the thickness must be enough for electrolyte permeation through the layer. Preferably, the layer is from 100 nm to 1 mm, more preferably from 500 nm to 10 μm. The self-organizing control structure to be the model of the photonic crystal of the invention is preferably a cubic closest packing structure, a hexagonal closet packing structure, or a face-centered cubic structure.

The particle size of the particles employed in the above (1) is preferably from 1 nm to 500 μm, more preferably from 150 nm to 10 μm. The material of the particles is not specifically defined, including, for example, inorganic oxide particles such as silica, alumina, zirconia, titania, ceria, tin oxide, calcia, magnesia, chromia, ferrite, zinc oxide; various polymer such as polystyrene, polyacrylate, fluororesin, silicone resin; micelles and reversed micelles with lipid and surfactant; natural compounds such as metal, pollen; and phosphates, silicates, etc. In particular, those that are readily dispersible are more preferred.

The material of the substrate employed in the above (1) is not also specifically defined, including, for example, ceramics such as alumina, zirconia, mullite, silicon carbide; glass, metal, plastics, electrode material, magnetic material, as well as their composites, laminates and coated articles. However, when the substrate serves as the electrode of the photoelectric conversion device for a solar cell, then it is preferably a transparent electrode such as typically ITO glass.

The method of applying the particles to the surface of the substrate in the above (1) may be any ordinary coating method of, for example, spraying, spin coating, flow coating, dipping, roll coating, gravure coating, brushing, sponge coating, etc. In addition, the method described in JP-A-8-229474 is also employable herein.

The photoelectric conversion substance usable herein includes, for example, titanium oxide, zinc oxide, strontium titanate, tin oxide, tungsten trioxide, dibismuth trioxide, ferric oxide, zirconia, etc. For fixing the photoelectric conversion substance in the gap of the particulate layer and on the particles, the photoelectric conversion substance and/or a photoelectric conversion substance precursor are applied to the layer. Preferably, the photoelectric conversion substance that is applied to the layer is a sol dispersion thereof. Specifically, a photoelectric conversion substance sol dispersion is applied thereto in an ordinary coating method of, for example, electrophoresis, spraying, spin coating, flow coating, dipping, roll coating, gravure coating, brushing, sponge coating, etc.

For example, when the photoelectric conversion substance is crystalline titanium oxide, then the photoelectric conversion substance precursor includes amorphous titanium oxide; organic titanium compounds such as titanium chelates, alkyl titanates, titanium acetates, titanium acetylacetonates; and inorganic titanium compounds such as titanium tetrachloride, titanium sulfate, etc. The same process as that for the sol mentioned above may apply also to the photoelectric conversion substance precursors. The step of converting the photoelectric conversion substance precursor into the corresponding photoelectric conversion substance particles thereof is described. For example, when the photoelectric conversion substance is crystalline titanium oxide, then the step is for finally converting the photoelectric conversion substance precursor into the crystalline titanium oxide. When the photoelectric conversion substance precursor is amorphous titanium oxide, then the step is for crystallizing it into anatase-type titanium oxide or rutile-type titanium oxide, for example, by heating the photoelectric conversion substance precursor. When the photoelectric conversion substance precursor is an organic titanium compound such as titanium chelates, alkyl titanates, titanium acetates, titanium acetylacetonates, or an inorganic titanium compound such as titanium tetrachloride, titanium sulfate, then it is hydrolyzed or polycondensed to give amorphous titanium oxide, and then the resulting amorphous titanium oxide is crystallized into anatase-type titanium oxide or rutile-type titanium oxide, for example, by heating it.

The photonic crystal consisting essentially of a photoelectric conversion substance, as referred to herein, is in such a condition that it contains a photoelectric conversion substance to such a degree that the electrons generated through excitation of the light-emitting dye contained inside the photonic crystal can be converted into electric energy.

Preferred combinations of the photoelectric conversion substance and the light-emitting dye in the invention are, for example, titanium oxide and ruthenium dye; titanium oxide and merocyanine dye; zinc oxide and eosine dye.

The step of removing a part and/or all of the particles described of the above (4) includes both a step of chemically removing a part and/or all of the particles, and a step of physically removing a part of the particulate layer. For the step of chemically removing a part of the particulate layer, for example, employable is a method of dissolution, vaporization or decomposition. For the step of physically removing a part of the particulate layer, for example, employable is a method of sputtering, cutting or polishing. Apart from these, a mechanochemical process may also be employed for the removal.

Not specifically defined, the dye for use in the invention may be any one having an absorption in the UV, visible and/or IR range and capable of emitting light in the UV, visible and/or IR range. The terminology, light emission as referred to herein does not always require the visibility of the emitted light. For example, it is meant to include a concept that the light-emitting dye is excited by sunlight and the excited electrons can be utilized as electric energy. Examples of the dye are ruthenium dyes, coumarin dyes, and porphyrin dyes. One or more of these dyes may be used herein. Preferably, however, one type of the dyes is used herein from the viewpoint of the retardation of the light emission by the dye. The method of incorporating the dye into the photonic crystal in the invention is not specifically defined. One example comprises infiltrating the dye into the crystal. The dye adsorption is preferably from 5.0⁻⁹ to 2. 0⁻⁵ mol/cm², more preferably from 5.09 to 1.0×10⁻⁵ mol/cm².

The mode of incorporating the light-emitting dye inside the photoelectric conversion substance is not specifically defined so far as the object of the invention can be attained. For example, in a combination of titanium oxide and ruthenium dye, the dye may be inside the photonic crystal that consists essentially of titanium oxide, in a mode of the following chemical bond.

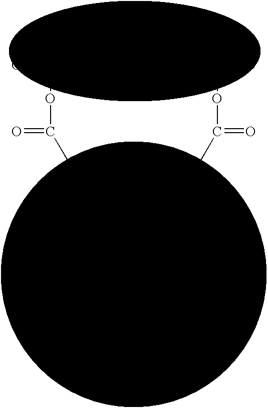

The photoelectric conversion device of the invention may be utilized as a solar cell. In this case, the electrolyte may be a liquid electrolyte, gel electrolyte or solid electrolyte that contains a redox species suitable to light-emitting dyes, such as amine-type, iodide-type or cobalt complexes. The counter electrode of the solar cell may be any of platinum, silver, copper, nickel, gold or the like. One example comprises an amine-type electrolyte; an ITO glass electrode and a platinum electrode kept in contact with the electrolyte; a photonic crystal layer that consists essentially of titanium oxide, provided on one or both faces of the ITO electrode; and a ruthenium dye contained inside the photonic crystal layer. In this, the photonic crystal may be the photoelectric conversion device that has a periodic structure of retarding the light emission by the dye therein.

### EXAMPLES

1. Determination of Periodic Structure:

In this Example, a ruthenium dye capable of being excited at 440 nm and emitting light at 630 nm was selected as the dye to be incorporated into a photoelectric conversion device. The photoelectric conversion substance is titanium oxide; the electrolyte is 0.6 M triethanolamine/0.5 M lithium perchlorate-acetonitrile solution; and the substrate is ITO glass. From these, it was decided to form a photonic crystal having a 519-nm periodic structure according to the calculation method described in Physical Review B66, 045102, 2002.

2. Formation of Photonic Crystal:

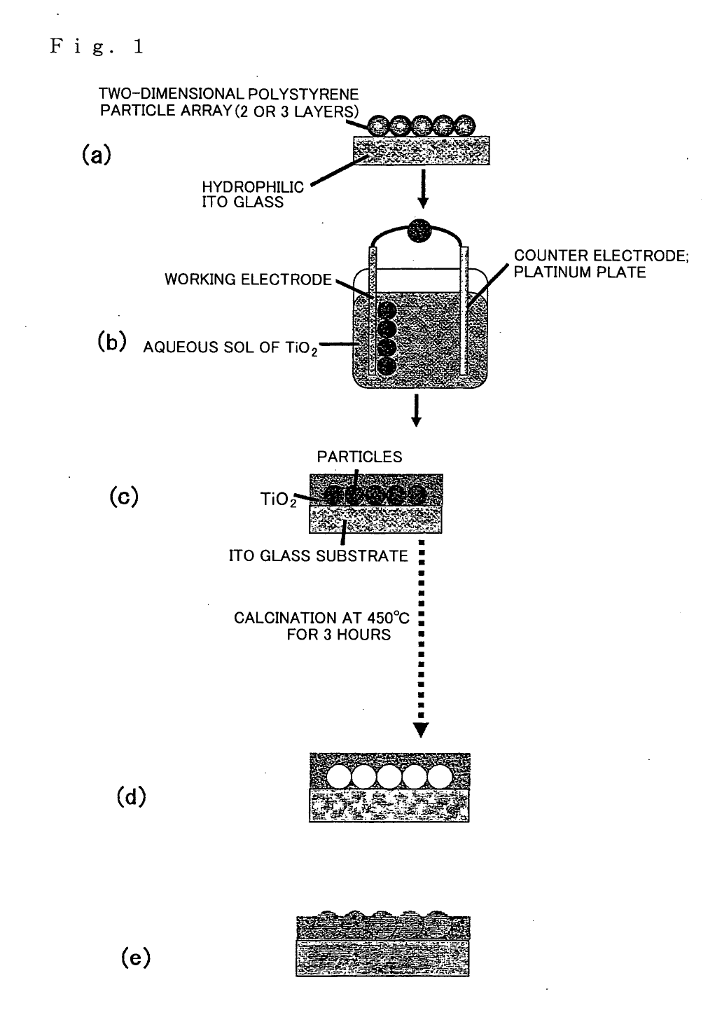

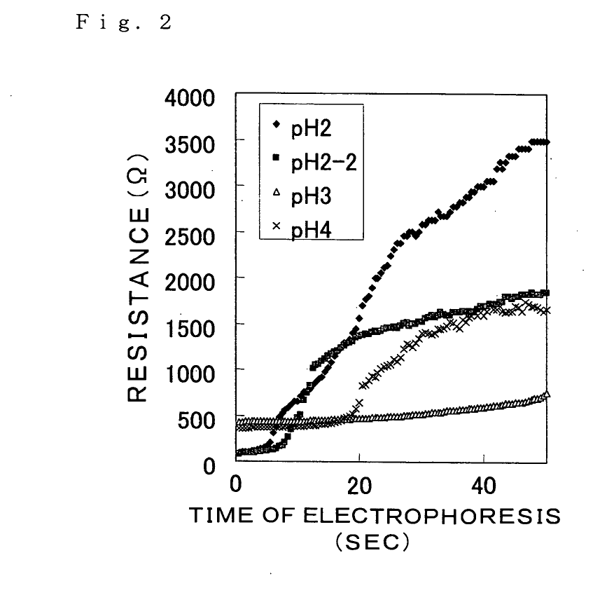

The photonic crystal was formed according to the method shown in FIG. 1. ITO glass (Asahi Glass' Lot No. 10Ω) was dipped in 0.1 M NaOH solution for 30 minutes and was thereby hydrophilicated. Next, monodispersed polystyrene particles having a particle size of 519 nm (Duke Scientific's Lot No. 5051A) were aligned in a self-organizing manner by utilizing the meniscus surface tension and capillary force (FIG. 1A). Thus formed, the self-organizing control structure of the particles was left in a thermostat at 80° C. for 2 hours and the particles were fused together. Next, a titanium oxide layer was formed on it in a mode of electrophoresis (see J. Am. Chem. Soc., 2001, 123, 175) (FIG. 1B). Concretely, an voltage of 10 V was applied to it for 140 seconds in an aqueous sol of titanium oxide (pH 2) (Sakai Chemical's Lot No. CSB-M), in which the self-organizing control structure of the particles serves as the working electrode and a platinum plate as the counter electrode. This gave a titanium oxide-polystyrene periodic structure (FIG. 1C). Next, the titanium oxide-polystyrene periodic structure thus obtained was calcinated in an electric furnace at 450° C. for 3 hours (FIG. 1D). In this, the pH of the titanium oxide sol was 2, and this result from the investigation of various sols in a pH range of from 2 to 4, as in FIG. 2.

3. Identification of Photonic Crystal Obtained:

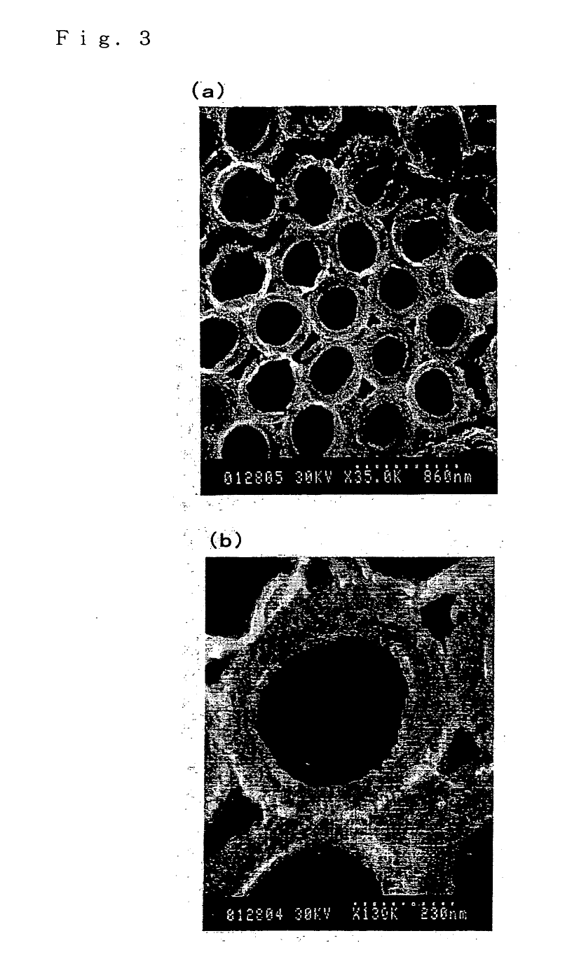

The same process as in the above 1 was carried out except that the time for voltage application was changed to 24 seconds, and electromicroscopic pictures of the photonic crystal obtained were taken. The reason for changing the voltage application time to 24 seconds is to clearly confirm the formation of the periodic structure on the pictures. This means that the picture taking was effected in the condition of FIG. 1E. The pictures are in FIG. 3. FIG. 3B is an enlarged picture of FIG. 3A. As in these, it is understood that the titanium oxide particles formed a self-organizing control structure and that the periodic structure thereof is 519 nm.

4. Dye Adsorption:

The photonic crystal obtained in the above 1 was dipped in 0.3 mM ruthenium dye/acetonitrile solution at 80° C., and then dried.

5. Measurement of Photon-To-Electron Conversion Efficiency:

The photon-to-electron conversion efficiency of the dye-containing photonic crystal obtained in the above 3 was measured according to the process shown in FIG. 4. Concretely, the photonic crystal was dipped in 0.6 M triethanolamine/0.5 M lithium perchlorate-acetonitrile solution, in which the surface of the crystal obtained in the above 4 serves as the working electrode and a platinum plate as the counter electrode. This process was so controlled that the surface of the photonic crystal dipped in the solution could be 0.25 mm². Then, light having a wavelength of from 400 to 540 nm was radiated to the surface of the photonic crystal through a monochrometer at intervals of 10 nm, whereupon the current running between the electrodes was measured.

6. Analysis of Comparative Samples:

The same ITO substrate as in the above 1, on which, however, a self-organizing control structure was not formed, was analyzed for the current running between the electrodes in the same manner as in the above 1, 3 and 4.

7. Photon-To-Electron Conversion Efficiency of Incident Monochromatic Light:

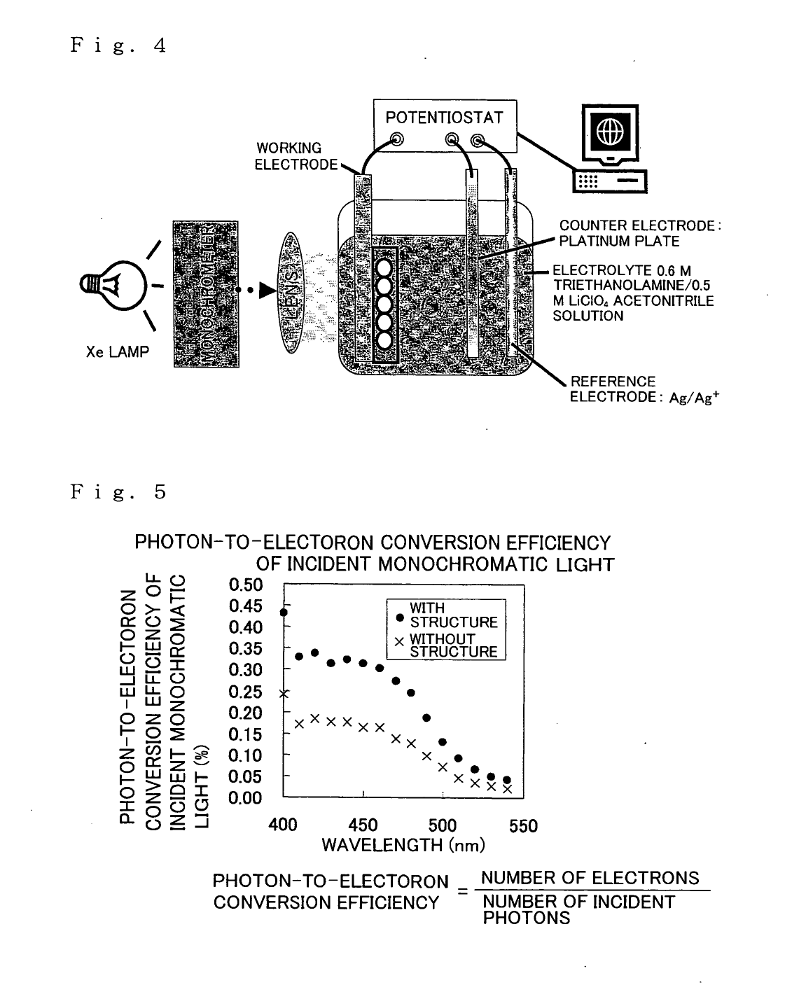

FIG. 5 shows the data obtained by dividing the number of electrons having run at each wavelength, by the number of photons (this is herein under referred to as a photon-to-electron conversion efficiency of incident monochromatic light). FIG. 5 confirms that the photon-to-electron conversion efficiency of incident monochromatic light increased to about 1.5 times.

8. Photon-To-Electron Conversion Efficiency per One Dye:

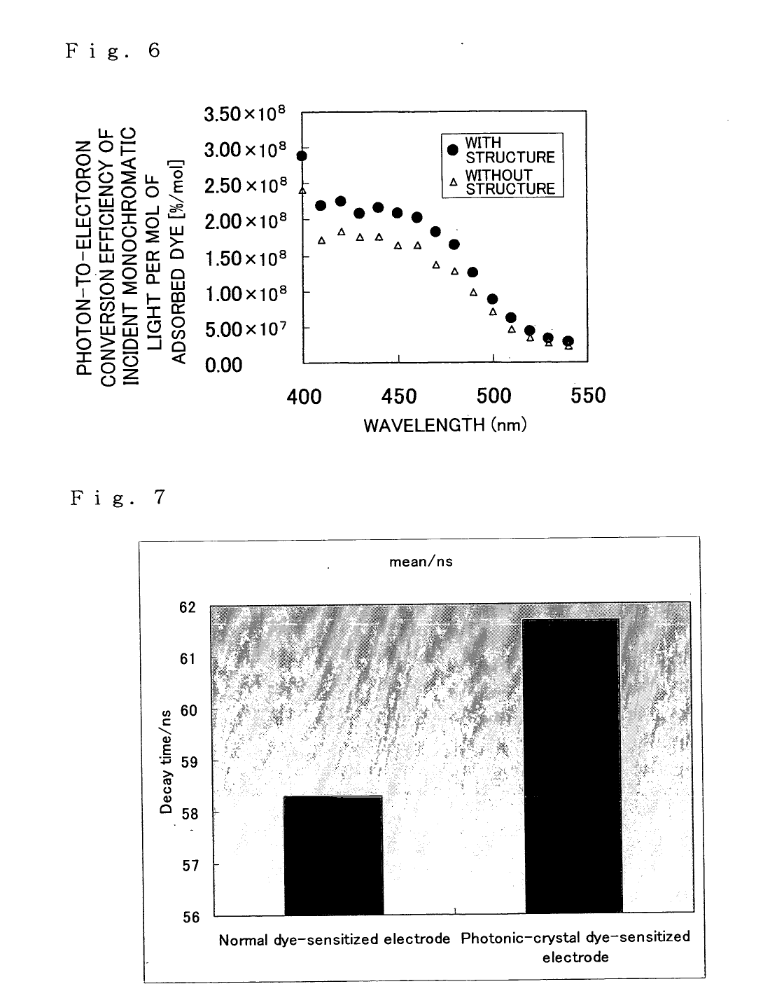

The following experiment is to confirm the advantage of the invention in that the effect of the invention is not the surface area increasing effect attained by the photonic crystal but the effect of the dye shut up inside the photonic crystal. Concretely, the photonic crystal obtained in the above 4 and the comparative sample of the above 6 were separately kept in pure water overnight so that the dye was dissolved out in the pure water. From the amount of the dye in the pure water, the number of the dye molecules contained in each sample was calculated. The photon-to-electron conversion efficiency of incident monochromatic light in the above 6 was divided by the number of the dye molecules, and it gives the photon-to-electron conversion efficiency per one molecule of the dye. The dye adsorption was 6.0×10⁻⁹ mol/cm² when the sample had a photonic crystal structure, and was 4.0×10⁻⁹ mol/cm² when the sample did not have it. The results are shown in FIG. 6. As in FIG. 6, it is understood that the efficiency per one dye molecule of the photoelectric conversion device of the invention increased to 1.2 times.

9. Life Change in the Presence or Absence of Photonic Crystal:

To further confirm the effect of the photonic crystal of the invention, the life of the electrons excited by the light-emitting dye in the crystal was measured. Specifically, a longer life of the electrons excited by the light-emitting dye suggests more efficient movement of the electrons toward titanium oxide.

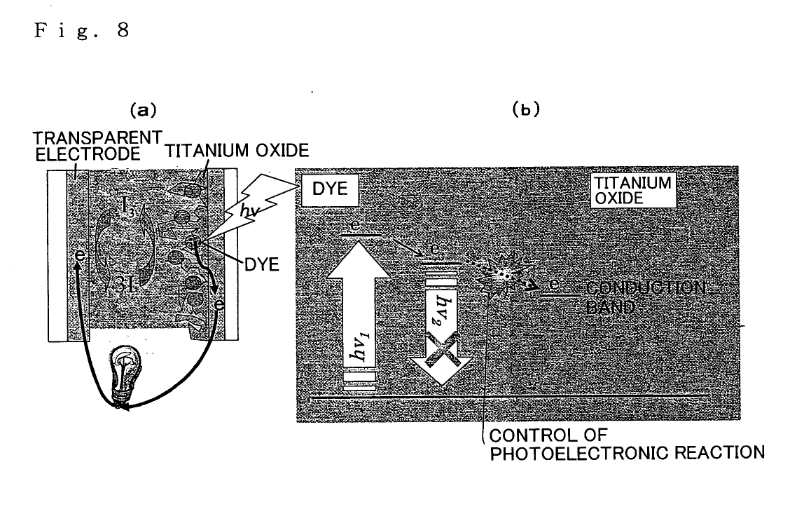

Concretely, the dye in the photonic crystal obtained in the above 4 and that in the comparative sample of the above 6 were separately excited by a wavelength-variable laser at a wavelength of 490 nm, and the time-dependent change in the light emission from each sample within a wavelength range of from 630 to 680 nm was determined by the use of a streak camera. As a result, regarding the component to cause the electron implantation from the dye to titanium oxide, the photonic crystal electrode of the invention prolonged the excited electron life by 3 nanoseconds or so (FIG. 7), and the results suggest that the retardation in the light emission process may cause the improvement in the photon-to-electron conversion efficiency of the device.

Employing the photoelectric conversion device of the invention makes it possible to prevent the excited electrons of the light-emitting dye in the device from being used for light emission, and the efficiency of the photoelectric conversion device is thereby improved.

The advantages of the photoelectric conversion device of the invention are that it may be down-sized into ultra-small devices, may be modified into power-saving devices (with reduction in insertion loss), and may be integrated into large-scale parallel devices; its costs may be reduced; it may be readily packaged into assemblies; and it has good properties in point of the temperature profile, the mass-producibility, the reliability and the multi-stage connectability to optical fibers and other devices. Accordingly, the industrial applicability of the photoelectric conversion device of the invention is much expected.

The present disclosure relates to the subject matter contained in Japanese Patent Application No. 303979/2003 filed on Aug. 28, 2003, which is expressly incorporated herein by reference in its entirety.

The foregoing description of preferred embodiments of the invention has been presented for purposes of illustration and description, and is not intended to be exhaustive or to limit the invention to the precise form disclosed. The description was selected to best explain the principles of the invention and their practical application to enable others skilled in the art to best utilize the invention in various embodiments and various modifications as are suited to the particular use contemplated. It is intended that the scope of the invention not be limited by the specification, but be defined claims set forth below.

1. A photoelectric conversion device, which comprises a photonic crystal consisting essentially of a photoelectric conversion substance, and a light-emitting dye contained inside the photonic crystal, and in which the photonic crystal has a periodic structure that retards the light emission by the light-emitting dye.

2. The photoelectric conversion device as claimed in claim 1, wherein the light-emitting dye has an absorption in the UV, visible and/or IR range and can emit light in the UV, visible and/or IR range.

3. The photoelectric conversion device as claimed in claim 1, wherein the light-emitting dye is any one or more of ruthenium dyes, coumarin dyes and porphyrin dyes.

4. The photoelectric conversion device as claimed in claim 1, wherein the light-emitting dye is a ruthenium dye.

5. The photoelectric conversion device as claimed in claim 1, wherein the photoelectric conversion substance is any one or more of titanium oxide, zinc oxide, strontium titanate, tin oxide, tungsten trioxide, dibismuth trioxide, ferric oxide and zirconia.

6. The photoelectric conversion device as claimed in claim 1, wherein the photoelectric conversion substance is titanium oxide.

7. The photoelectric conversion device as claimed in claim 1, wherein the light-emitting dye is a ruthenium dye and the photoelectric conversion substance is titanium oxide.

8. The photoelectric conversion device as claimed in claim 1, wherein the photonic crystal contains the following structure:

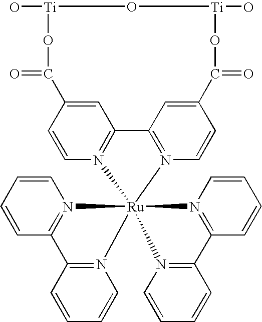

9. The photoelectric conversion device as claimed in claim 1, wherein the thickness of the photonic crystal layer is from 500 nm to 1 mm.

10. The photoelectric conversion device as claimed in claim 1, wherein the photonic crystal contains the light-emitting dye in an amount of from 5.0⁻⁹ to 2.0⁻⁵ mol per 1 cm² of the surface of the photonic crystal.

11. The photoelectric conversion device as claimed in claim 1, wherein the photonic crystal has any of a cubic closest packing structure, a hexagonal closet packing structure, or a face-centered cubic structure.

12. A photoelectric conversion device, which comprises an electrolyte, a first electrode and a second electrode kept in contact with the electrolyte, a photonic crystal layer consisting essentially of a photoelectric conversion substance and provided on one face or both faces of the first electrode, and a light-emitting dye contained inside the photonic crystal layer, and in which the photonic crystal has a periodic structure that retards the light emission by the light-emitting dye.

13. The photoelectric conversion device as claimed in claim 12, wherein the electrolyte is one or more of amine-type, iodide ion-type and cobalt complexes.

14. The photoelectric conversion device as claimed in claim 12, wherein the first electrode is an ITO glass electrode.

15. The photoelectric conversion device as claimed in claim 12, wherein the second electrode is formed of any of platinum, silver, copper, nickel or gold.

16. The photoelectric conversion device as claimed in claim 12, wherein the first electrode is an ITO glass electrode and the second electrode is formed of platinum.

17. A solar cell comprising the photoelectric conversion device of claim 12.
